(19) United States
(12) Patent Application Publication
(10) Pub. No.: US 2024/0085782 A1
(43) Pub. Date: Mar. 14, 2024

(54) RESIDUAL LAYER THICKNESS MODULATION IN NANOIMPRINT LITHOGRAPHY

(71) Applicant: GOOGLE LLC, Mountain View, CA (US)

(72) Inventors: Wei Jin, Saratoga, CA (US); Lu Tian, Palo Alto, CA (US); Thomas Mercier, Weston, FL (US)

(21) Appl. No.: 17/932,016

(22) Filed: Sep. 14, 2022

(51) Int. Cl. G03F 7/00; F21V 8/00; G03F 7/16

(52) U.S. Cl. CPC G03F 7/0002; G02B 6/0065; G03F 7/162; G02B 6/0026; G02B 6/005

(57) ABSTRACT

An improved nanoimprint lithography process is presented in which the height is controlled by the thickness of a residual layer of resin leftover after ultraviolet curing and releasing of a nanoimprint mold from a resin layer. Moreover, the thickness of the residual layer may be controlled by a fill factor of either a nanoimprint mold that transfers its pattern to a resin layer disposed on a substrate, or by droplets of resin in the resin layer.

### BACKGROUND

This disclosure is directed to techniques for manufacturing components of waveguides for augmented and mixed-reality applications.

### SUMMARY

Implementations described herein are related to manufacturing components such as light incouplers and outcouplers for waveguides in smartglasses systems. Such components may include diffraction gratings having a continuous height profile. Conventional manufacturing techniques for such gratings include a multi-level process which approximates the height profile to a specified degree. A better approximation to the height profile often requires more levels in the manufacturing process. In many cases, obtaining a sufficiently good approximation to a given height profile involves many levels in a single process, making the manufacture of the components time-consuming and expensive. In contrast, a nanoimprint lithography process in which the height is controlled by the thickness of a residual layer of resin leftover after ultraviolet curing and releasing of a nanoimprint mold from a resin layer offers the ability to produce a height profile in a single step.

In one general aspect, a nanoimprint lithography system includes a nanoimprint mold having a base and a binary height grating structure, the binary height grating structure having a first fill factor over a first portion of the base and a second fill factor over a second portion of the base. The nanoimprint lithography apparatus also includes a substrate on which a resin layer is deposited, the substrate having a first portion corresponding to the first portion of the base of the nanoimprint mold and a second portion corresponding to the first portion of the base of the nanoimprint mold. The nanoimprint lithography apparatus further includes a mold embedding device configured to embed the nanoimprint mold into the resin layer to a depth such that a thickness of the resin layer between an end of the binary height grating structure of the mold opposite the base and the substrate is greater than zero. The nanoimprint lithography apparatus further includes an ultraviolet curing device configured to cure the resin layer while the mold is embedded in the resin layer to the depth to produce a residual layer of resin between the end of the binary height grating structure of the mold opposite the base and the substrate, the residual layer having a first thickness disposed on the first portion of the substrate and a second thickness disposed on the second portion of the substrate.

In another general aspect, a nanoimprint lithography system includes a nanoimprint mold having a base and a binary height grating structure. The nanoimprint lithography apparatus also includes a substrate on which a resin layer is deposited, the substrate having a first portion and a second portion, the resin layer having a first fill factor over a first portion of the substrate and a second fill factor over a second portion of the substrate. The nanoimprint lithography apparatus further includes a mold embedding device configured to embed the nanoimprint mold into the resin layer to a depth such that a thickness of the resin layer between an end of the binary height grating structure of the mold opposite the base and the substrate is greater than zero. The nanoimprint lithography apparatus further includes an ultraviolet curing device configured to cure the resin layer while the mold is embedded in the resin layer to the depth to produce a residual layer of resin between the end of the binary height grating structure of the mold opposite the base and the substrate, the residual layer having a first thickness disposed on the first portion of the substrate and a second thickness disposed on the second portion of the substrate.

In another general aspect, a method includes embedding a nanoimprint mold into a resin layer to a depth such that a thickness of the resin layer between an end of a binary height grating structure of the nanoprint mold opposite the base and a substrate on which the resin layer is disposed is greater than zero, the nanoimprint mold having a base and a binary height grating structure, the binary height grating structure having a first fill factor over a first portion of the base and a second fill factor over a second portion of the base, the substrate having a first portion corresponding to the first portion of the base of the nanoimprint mold and a second portion corresponding to the first portion of the base of the nanoimprint mold. The method also includes curing the resin layer while the mold is embedded in the resin layer to the depth to produce a residual layer of resin between the end of the binary height grating structure of the mold opposite the base and the substrate, the residual layer having a first thickness disposed on the first portion of the substrate and a second thickness disposed on the second portion of the substrate.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an example waveguide with incoupler and outcoupler components.

FIG. 2 is a plot illustrating an example variation of residual layer thickness in a nanoimprint lithography system with nanoimprint mold fill factor.

FIGS. 3A through 3D are diagrams illustrating an example improved nanoimprint lithography process for controlling residual layer thickness via the nanoimprint mold.

FIGS. 4A through 4D are diagrams illustrating an example improved nanoimprint lithography process for controlling residual layer thickness via the resin layer.

FIG. 5 is a flowchart illustrating an example method for performing nanoimprint lithography.

FIG. 6 is a diagram illustrating example smartglasses using a waveguide with components manufactured according to the improved nanoprint lithography process.

### DETAILED DESCRIPTION

This disclosure relates to manufacturing components such as light incouplers and outcouplers for waveguides in smartglasses systems. Such components may include diffraction gratings having a continuous height profile. A better approximation to the height profile often requires more levels in the manufacturing process. In many cases, obtaining a sufficiently good approximation to a given height profile involves many levels in a single process, making the manufacture of the components time-consuming and expensive. In contrast, a nanoimprint lithography process in which the height is controlled by the thickness of a residual layer of resin leftover after ultraviolet curing and releasing of a nanoimprint mold from a resin layer offers the ability to produce a height profile in a single step.

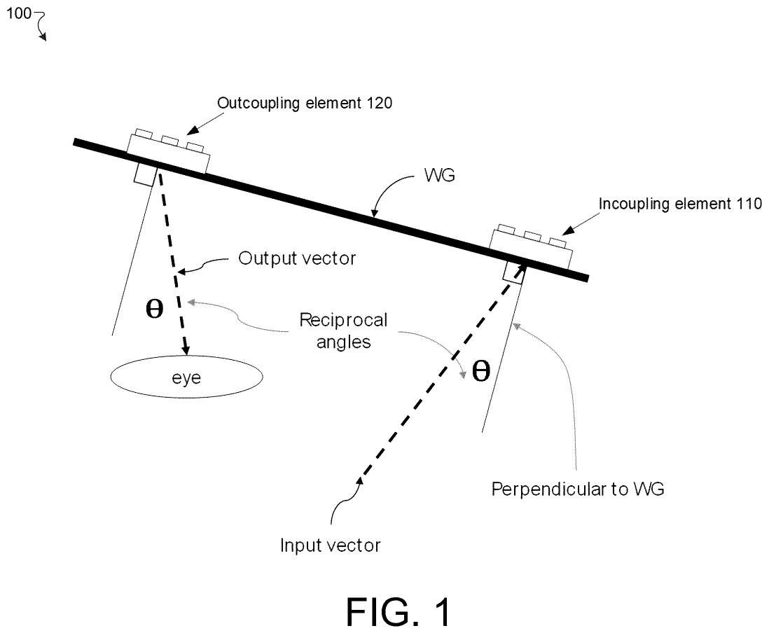

FIG. 1 illustrates an example waveguide (WG) 100 with incoupler and outcoupler components 110 and 120, respectively. As shown in FIG. 1, light from a projection system propagates toward the waveguide 100 at an input vector θ with respect to the waveguide normal. The incoupler 110 includes a diffraction grating that takes the light from the input vector θ and is designed so that most of the light energy is directed toward a diffracted order that propagates down the waveguide 100 (i.e., as a waveguide mode) in the direction of the outcoupler 120. When the light in the waveguide is incident on the outcoupler 120, which has an equivalent diffraction grating as the incoupler 110, the outcoupler 120 provides a reciprocal action to that of the incoupler 110 and sends most of the light energy out of the waveguide 100 and into the output vector shown in FIG. 1, the output vector being a mirror image of the input vector.

The special purpose of the incoupler 110 and the outcoupler 120 in directing light in and out of the waveguide 100 at specific angles of propagation (i.e., total internal reflection) may dictate that the incoupler 110 and outcoupler 120 have specific, continuous height profiles. Because the feature sizes of the diffraction gratings of the incoupler 110 and outcoupler 120 are very small, e.g., less than 5 microns, techniques of manufacturing the diffraction gratings of the incoupler 110 and the outcoupler 120 may include microlithographic techniques.

Conventional manufacturing techniques for the diffraction gratings include a multi-level process which approximates the height profile to a specified degree: the better approximation to the height profile, the more levels in the manufacturing process are required.

A technical problem with the above-described conventional manufacturing techniques is that in many cases, getting a sufficiently good approximation to a given height profile involves many levels in a single process, making the manufacture of the components time-consuming and expensive. For example, if a height profile resembles a smooth ramp, a multi-level process may produce a staircase profile. A two- or three-level process produces large steps that may provide a poor approximation. A ten-level approximation produces many small steps that provide a good approximation, but unfortunately this many levels is very expensive and time-consuming.

In accordance with the implementations described herein, a technical solution to the above-described technical problem includes an improved nanoimprint lithography process in which the height is controlled by the thickness of a residual layer of resin leftover after ultraviolet curing and releasing of a nanoimprint mold from a resin layer. Moreover, the thickness of the residual layer may be controlled by a fill factor of either a nanoimprint mold that transfers its pattern to a resin layer disposed on a substrate, or by droplets of resin in the resin layer.

A technical advantage of the technical solution is that the improved nanoimprint lithography process can achieve a desired height profile in a single step rather than in multiple steps using the conventional process. Accordingly, the technical solution can save time and reduce the cost of manufacturing the waveguide components.

In some implementations, a nanoimprint lithography system implementing the improved nanoimprint lithography process includes a dry etch device configured to etch the resin layer after the nanoimprint mold has been released from the resin layer.

In some implementations, the dry etch device is configured to etch the resin layer with an etch selectivity equal to that for a dielectric film.

In some implementations, the first fill factor is less than the second fill factor, and the first thickness of the residual layer is greater than the second thickness of the residual layer.

In some implementations, the nanoimprint mold includes quartz.

In some implementations, the nanoimprint mold and the substrate each include silicon.

In some implementations, the resin layer is disposed on the substrate via a spin-coating process.

In some implementations, the resin layer includes droplets of resin disposed on the substrate.

In some implementations, the resin layer having the first fill factor over the first portion of the substrate includes droplets having a first size and the resin layer having the second fill factor over the second portion of the substrate includes droplets having a second size.

The above-described improved nanoimprint lithography process is based on an observation that the residual layer of resin left over after ultraviolet curing and release of the nanoimprint mold has a thickness roughly inversely proportional to a fill factor of a mold or resin layer pattern. The fill factor (duty cycle) of the nanoimprint mold is defined herein as the ratio of a width of a mold feature to the pitch. For example, if the mold has equal lines and spaces, its fill factor is ½; if in contrast the width of a line is twice as wide as the space then the fill factor is ⅔. The fill factor of the resin layer may be defined in the case where the resin is deposited as droplets on a substrate. In that case, the fill factor for the resin is the ratio of a size (e.g., diameter, width) of a droplet to the pitch.

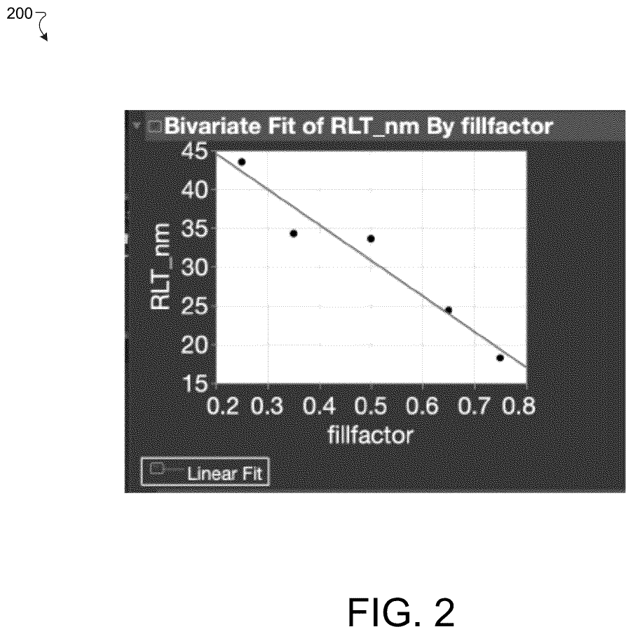

FIG. 2 is a plot 200 illustrating an example variation of residual layer thickness in a nanoimprint lithography system with nanoimprint mold fill factor. As shown in FIG. 2, the residual layer thickness is roughly inversely proportional to the fill factor of wither the nanoimprint mold of the resin layer. This means that the residual layer thickness may be controlled with the fill factor of either the nanoimprint mold or the resin layer. This in turn will enable the manufacture of diffraction gratings having continuous height profiles in a single step.

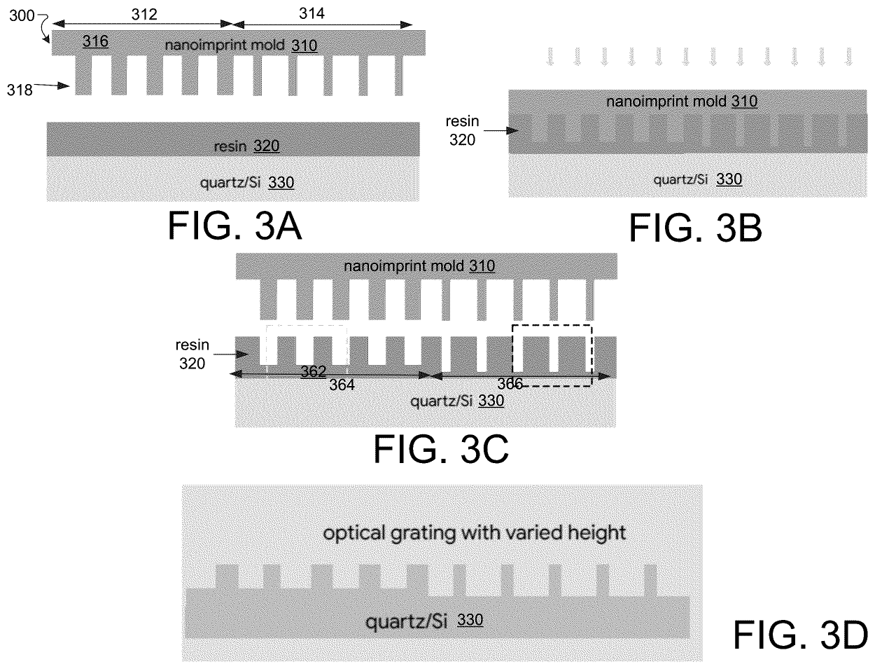

FIGS. 3A through 3D are diagrams illustrating an example nanoimprint lithography process for controlling residual layer thickness via the nanoimprint mold 310. Along with the nanoimprint model 310, the process is defined by the substrate 330 on which a resin layer 320 is disposed. In the process, in some implementations, the resin layer 320 is deposited on the substrate 330 using a spin coat process. Because the residual layer is not only desired but is to be controlled, the spin coat process should be defined to allow for sufficient residual resin.

In FIG. 3A, the nanoimprint mold 310 is produced. In some implementations, the nanoimprint mold 310 includes quartz. In some implementations, the nanoimprint mold 310 and the substrate 330 each include silicon. The nanoimprint mold 310 has a base 316 and binary height grating structure 318, the binary height grating structure 318 having a first fill factor over a first portion 312 of the base 316 and a second fill factor over a second portion 314 of the base 316. Moreover, the resin layer 320 is spin-coated over the substrate 330.

In FIG. 3B, the nanoimprint mold 310 is embedded into the resin layer 320 to a depth such that a thickness of the resin layer 320 between an end of the binary height grating structure 318 of the mold 310 opposite the base 316 and the substrate 330 is greater than zero.

In FIG. 3C, the nanoimprint mold 310 is released from the resin layer 320 and ultraviolet cured to produce residual layer 362 of resin between the end of the binary height grating structure 318 of the mold 310 opposite the base 316 and the substrate 330, the residual layer 362 having a first thickness disposed on the first portion 364 of the substrate and a second thickness disposed on the second portion 366 of the substrate. In some implementations, the first fill factor is less than the second fill factor, and the first thickness of the residual layer 362 is greater than the second thickness of the residual layer 362.

In FIG. 3D, the diffraction grating is produced by a dry etch device configured to etch the resin layer 320 after the nanoimprint mold 310 has been released from the resin layer 320. In some implementations, the dry etch device is configured to etch the resin layer with an etch selectivity equal to that for a dielectric film.

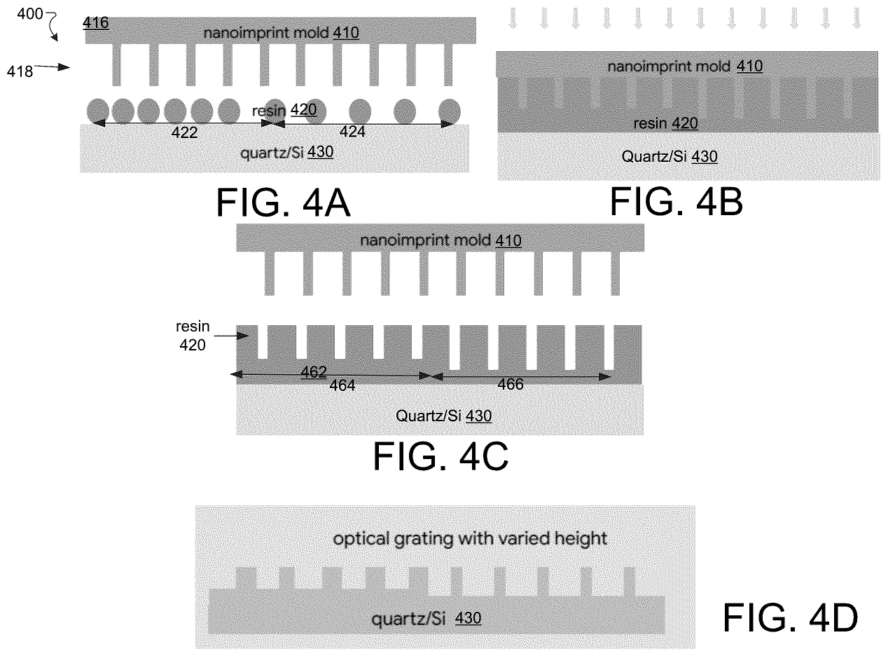

FIGS. 4A through 4D are diagrams illustrating an example nanoimprint lithography process for controlling residual layer thickness via the resin layer. Along with the resin layer 420, the process is defined by the nanoimprint mold 410 and the substrate 430 on which the resin layer 420 is disposed.

In FIG. 4A, a nanoimprint mold 410 having a base 416 and a binary height grating structure 418 is produced. Also, a substrate 430 on which a resin layer 420 is deposited, the substrate having a first portion 422 corresponding to the first portion of the base 416 of the nanoimprint mold 410 and a second portion 424 corresponding to the first portion of the base 416 of the nanoimprint mold 410 is produced. In some implementations and as shown in FIG. 4A, the resin layer 420 includes droplets of resin disposed on the substrate 430. In some implementations, the resin layer 420 has the first fill factor over the first portion 422 of the substrate 430 includes droplets having a first size and the resin layer having the second fill factor over the second portion 424 of the substrate 430 includes droplets having a second size.

In FIG. 4B, the nanoimprint mold 410 is embedded into the resin layer 420 to a depth such that a thickness of the resin layer 420 between an end of the binary height grating structure 418 of the mold 410 opposite the base 416 and the substrate 430 is greater than zero.

In FIG. 4C, the nanoimprint mold 410 is released from the resin layer 420 and ultraviolet cured to produce a residual layer 462 of resin between the end of the binary height grating structure 418 of the mold 410 opposite the base 416 and the substrate 430, the residual layer having a first thickness disposed on the first portion 464 of the substrate 430 and a second thickness disposed on the second portion 466 of the substrate 430.

In FIG. 4D, the diffraction grating is produced by a dry etch device configured to etch the resin layer 420 after the nanoimprint mold 410 has been released from the resin layer 420. In some implementations, the dry etch device is configured to etch the resin layer with an etch selectivity equal to that for a dielectric film.

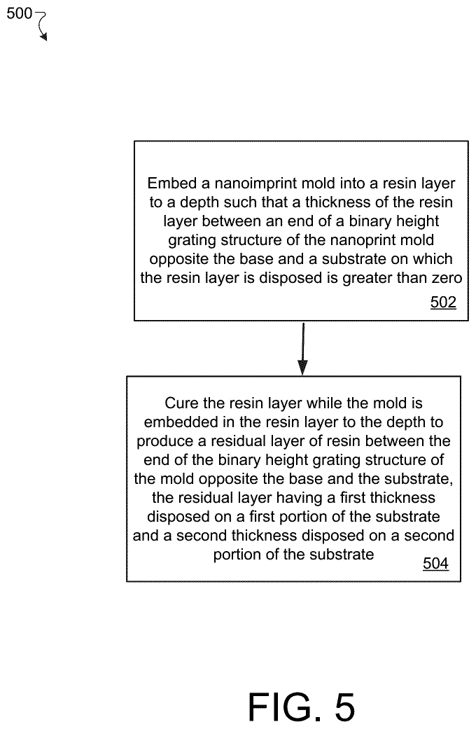

FIG. 5 is a flowchart illustrating an example method 500 for performing nanoimprint lithography.

At 510, a nanoimprint mold is embedded into a resin layer to a depth such that a thickness of the resin layer between an end of a binary height grating structure of the nanoprint mold opposite the base and a substrate on which the resin layer is disposed is greater than zero, the nanoimprint mold having a base and a binary height grating structure, the binary height grating structure having a first fill factor over a first portion of the base and a second fill factor over a second portion of the base, the substrate having a first portion corresponding to the first portion of the base of the nanoimprint mold and a second portion corresponding to the first portion of the base of the nanoimprint mold.

At 520, the resin layer is cured while the mold is embedded in the resin layer to the depth to produce a residual layer of resin between the end of the binary height grating structure of the mold opposite the base and the substrate, the residual layer having a first thickness disposed on the first portion of the substrate and a second thickness disposed on the second portion of the substrate.

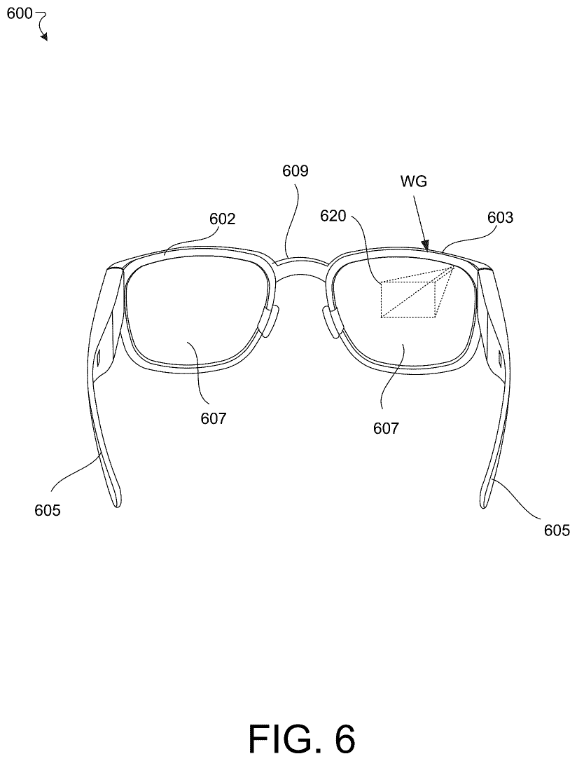

FIG. 6 is a diagram illustrating example smartglasses 600 using a waveguide with components manufactured according to the improved nanoprint lithography process. The example smartglasses 600 includes a frame 602. The frame 602 includes a front frame portion defined by rim portions 603 surrounding respective optical portions in the form of lenses 607, with a bridge portion 609 connecting the rim portions 603. Arm portions 605 are coupled, for example, pivotably or rotatably coupled, to the front frame by hinge portions at the respective rim portion 603. A display device may be coupled in a portion of the frame 602. In the example shown in FIG. 6, the display device is coupled in the arm portion 605 of the frame 602. In some examples, the display device may be configured to project light from a display source onto a portion of teleprompter glass functioning as a beamsplitter seated at an angle (e.g., 30-45 degrees). The beamsplitter may allow for reflection and transmission values that allow the light from the display source to be partially reflected while the remaining light is transmitted through. Such an optic design may allow a user to see both physical items in the world, for example, through the lenses 607, next to content (for example, digital images, user interface elements, virtual content, and the like) generated by the display device 104. In some implementations, the waveguide WG may be used to depict content on the display device via outcoupled light 620 (i.e., from an outcoupler).

A number of implementations have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite example relationships described in the specification or shown in the figures.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

What is claimed is:

1. A nanoimprint lithography system, comprising:
a nanoimprint mold having a base and a binary height grating structure, the binary height grating structure having a first fill factor over a first portion of the base and a second fill factor over a second portion of the base;
a substrate on which a resin layer is deposited, the substrate having a first portion corresponding to the first portion of the base of the nanoimprint mold and a second portion corresponding to the first portion of the base of the nanoimprint mold;
a mold embedding device configured to embed the nanoimprint mold into the resin layer to a depth such that a thickness of the resin layer between an end of the binary height grating structure of the nanoimprint mold opposite the base and the substrate is greater than zero; and
an ultraviolet curing device configured to cure the resin layer while the nanoimprint mold is embedded in the resin layer to the depth to produce a residual layer of resin between the end of the binary height grating structure of the nanoimprint mold opposite the base and the substrate, the residual layer having a first thickness disposed on the first portion of the substrate and a second thickness disposed on the second portion of the substrate.

2. The nanoimprint lithography system as in claim 1, further comprising:
a dry etch device configured to etch the resin layer after the nanoimprint mold has been released from the resin layer.

3. The nanoimprint lithography system as in claim 2, wherein the dry etch device is configured to etch the resin layer with an etch selectivity equal to that for a dielectric film.

4. The nanoimprint lithography system as in claim 1, wherein the first fill factor is less than the second fill factor, and the first thickness of the residual layer is greater than the second thickness of the residual layer.

5. The nanoimprint lithography system as in claim 1, wherein the nanoimprint mold includes quartz.

6. The nanoimprint lithography system as in claim 1, wherein the nanoimprint mold and the substrate each include silicon.

7. The nanoimprint lithography system as in claim 1, wherein the resin layer is disposed on the substrate via a spin-coating process.

8. A nanoimprint lithography system, comprising:
a nanoimprint mold having a base and a binary height grating structure;
a substrate on which a resin layer is deposited, the substrate having a first portion and a second portion, the resin layer having a first fill factor over a first portion of the substrate and a second fill factor over a second portion of the substrate;
a mold embedding device configured to embed the nanoimprint mold into the resin layer to a depth such that a thickness of the resin layer between an end of the binary height grating structure of the nanoimprint mold opposite the base and the substrate is greater than zero; and
an ultraviolet curing device configured to cure the resin layer while the nanoimprint mold is embedded in the resin layer to the depth to produce a residual layer of resin between the end of the binary height grating structure of the nanoimprint mold opposite the base and the substrate, the residual layer having a first thickness disposed on the first portion of the substrate and a second thickness disposed on the second portion of the substrate.

9. The nanoimprint lithography system as in claim 8, wherein the resin layer includes droplets of resin disposed on the substrate.

10. The nanoimprint lithography system as in claim 9, wherein the resin layer having the first fill factor over the first portion of the substrate includes droplets having a first size and the resin layer having the second fill factor over the second portion of the substrate includes droplets having a second size.

11. The nanoimprint lithography system as in claim 8, further comprising:
a dry etch device configured to etch the resin layer after the nanoimprint mold has been released from the resin layer.

12. The nanoimprint lithography system as in claim 11, wherein the dry etch device is configured to etch the resin layer with an etch selectivity equal to that for a dielectric film.

13. The nanoimprint lithography system as in claim 8, wherein the first fill factor is less than the second fill factor, and the first thickness of the residual layer is greater than the second thickness of the residual layer.

14. A method, comprising:
embedding a nanoimprint mold into a resin layer to a depth such that a thickness of the resin layer between an end of a binary height grating structure of the nanoimprint mold opposite a base of the nanoimprint mold and a substrate on which the resin layer is disposed is greater than zero, the nanoimprint mold having a base and a binary height grating structure, the binary height grating structure having a first fill factor over a first portion of the base and a second fill factor over a second portion of the base, the substrate having a first portion corresponding to the first portion of the base of the nanoimprint mold and a second portion corresponding to the first portion of the base of the nanoimprint mold; and
curing the resin layer while the nanoimprint mold is embedded in the resin layer to the depth to produce a residual layer of resin between the end of the binary height grating structure of the nanoimprint mold opposite the base and the substrate, the residual layer having a first thickness disposed on the first portion of the substrate and a second thickness disposed on the second portion of the substrate.

15. The method as in claim 14, further comprising:
etching the resin layer after the nanoimprint mold has been released from the resin layer.

16. The method as in claim 15, the resin layer is etched with an etch selectivity equal to that for a dielectric film.

17. The method as in claim 14, wherein the first fill factor is less than the second fill factor, and the first thickness of the residual layer is greater than the second thickness of the residual layer.

18. The method as in claim 14, wherein the nanoimprint mold includes quartz.

19. The method as in claim 14, wherein the nanoimprint mold and the substrate each include silicon.

20. The method as in claim 14, wherein the resin layer is disposed on the substrate via a spin-coating process.
